(19) United States
(12) Patent Application Publication
(10) Pub. No.: US 2012/0032175 A1
(43) Pub. Date: Feb. 9, 2012

(54) DISPLAY STRUCTURE

(76) Inventors: Wen-Chun WANG, Taichung City (TW); Hsi-Rong Han, Taichung County (TW); Hsien-Wei Chiang, Tai Pei City (TW); Wen-Tui Liao, Tai Chung City (TW)

(21) Appl. No.: 13/198,150

(22) Filed: Aug. 4, 2011

(30) Foreign Application Priority Data
Aug. 6, 2010 (TW) 099126369

(51) Int. Cl. H01L 27/15

(52) U.S. Cl. 257/59; 257/E27.121

(57) ABSTRACT

A display structure includes a first transparent substrate, a second transparent substrate opposite the first transparent substrate, a display medium interposed between the first transparent substrate and the second transparent substrate, at least one first thin film transistor formed on the first transparent substrate, a first insulation layer formed on the first transparent substrate, a first electrode layer formed on the first insulation layer, an organic light-emitting layer formed on the first electrode layer and in a region not overlapping the first thin film transistor, a cathode layer formed on the organic light-emitting layer, and a second electrode layer formed on the second transparent substrate.

### BACKGROUND OF THE INVENTION

a. Field of the Invention

The invention relates to a display structure

b. Description of the Related Art

Nowadays, a portable electronic device such as a tablet computer or a smart phone may fulfill functions of on-line reading, animation display, etc., and these functions are realized by an organic light-emitting diode (OLED) display or a liquid crystal display (LCD). Since a portable electronic device is designed to have as much working hours as possible, how to reduce power consumption becomes a key issue towards current trends. Further, a power-saving electronic book reading device capable of storing massive reading materials may be constructed by a bistable display device, since its bistable characteristics offer the advantage of power saving on performing reading actions. However, compared with the response speed of an OLED device or an LCD device, the response speed of a bistable display device is relatively low. Therefore, the bistable display device is not suitable for animation display.

### BRIEF SUMMARY OF THE INVENTION

The invention provides a display structure having low power consumption and high response speed.

Other objects and advantages of the invention may be further illustrated by the technical features broadly embodied and described as follows. In order to achieve one or a portion of or all of the objects or other objects, one embodiment of the invention provides a display structure including a first transparent substrate, a second transparent substrate opposite the first transparent substrate, a display medium interposed between the first transparent substrate and the second transparent substrate, at least one first thin film transistor formed on the first transparent substrate, a first insulation layer formed on the first transparent substrate and covering the first thin film transistor, a first electrode layer formed on the first insulation layer, an organic light-emitting layer formed on the first electrode layer and in a region not overlapping the first thin film transistor, a cathode layer formed on the organic light-emitting layer, and a second electrode layer formed on the second transparent substrate. The second electrode layer is a transparent electrode layer.

In one embodiment, a black matrix layer is formed on the first electrode layer or interposed between the first electrode layer and the first insulation layer.

In one embodiment, the display medium layer is a cholesterol liquid crystal layer, an electrophoretic layer, or a polymer dispersed liquid crystal layer.

In one embodiment, at least one second thin film transistor is formed on the second transparent substrate

In one embodiment, either the first electrode layer or the cathode layer serves as a common electrode of the display structure.

In one embodiment, the second electrode layer serves as a common electrode of the display structure.

Another embodiment of the invention provides a display structure including a first transparent substrate, a second transparent substrate opposite the first transparent substrate, a display medium interposed between the first transparent substrate and the second transparent substrate, at least one first thin film transistor formed on the first transparent substrate, a first insulation layer formed on the first transparent substrate and covering the first thin film transistor, a first electrode layer formed on the first insulation layer, a second electrode layer formed on the second transparent substrate and electrically connected to the first electrode layer, where the second electrode layer is a transparent electrode layer, an organic light-emitting layer formed on the second electrode layer, and a cathode layer formed on the organic light-emitting layer.

In one embodiment, a bump structure is formed on the first transparent substrate or the second transparent substrate to connect the first electrode layer with the second electrode layer.

In one embodiment, the cathode layer serves as a common electrode of the display structure.

Another embodiment of the invention provides a display structure having at least one organic light-emitting diode (OLED) pixel and at least one bistable pixel adjacent to or opposite from each other, where the OLED pixel displays images when the bistable pixel is turned off, and the bistable pixel displays images when the OLED pixel is turned off.

In one embodiment, a Vdd voltage signal is in a low-level state when a write-in operation and an erase operation are performed on the bistable pixel, and the Vdd voltage signal is in a high-level state when the OLED pixel is turned on to display images.

The embodiment or the embodiments of the invention may have at least one of the following advantages. According to the above embodiments, the OLED pixel is self-luminous and has wide viewing angles, high brightness and high response speed. In comparison, the bistable pixel is power-saving due to bistable characteristics.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 shows a schematic diagram of a display structure according to an embodiment of the invention.

FIG. 2 shows a schematic cross-section illustrating electrode structures of a display structure according to an embodiment of the invention.

FIG. 3 shows a schematic cross-section illustrating electrode structures of a display structure according to another embodiment of the invention.

FIG. 4 shows a schematic cross-section illustrating electrode structures of a display structure according to another embodiment of the invention.

FIG. 5 shows a schematic cross-section illustrating electrode structures of a display structure according to another embodiment of the invention.

FIG. 6 shows a schematic cross-section illustrating electrode structures of a display structure according to another embodiment of the invention.

FIG. 7 shows a schematic cross-section illustrating electrode structures of a display structure shown in FIG. 6.

FIG. 8 shows a timing diagram illustrating a pixel drive scheme for a display structure according to an embodiment of the invention.

### DETAILED DESCRIPTION OF THE INVENTION

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

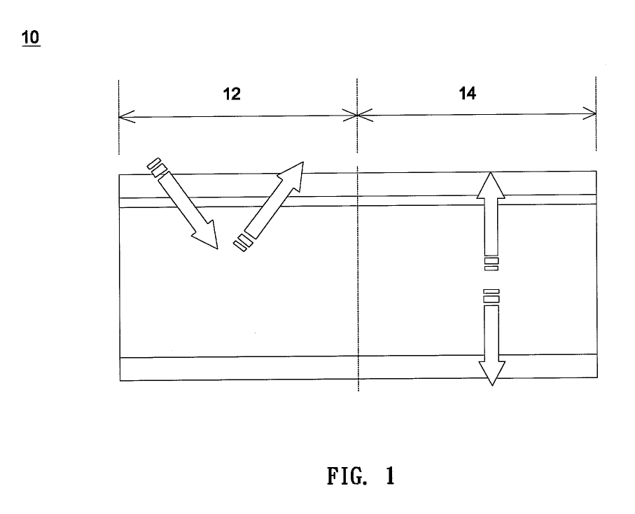

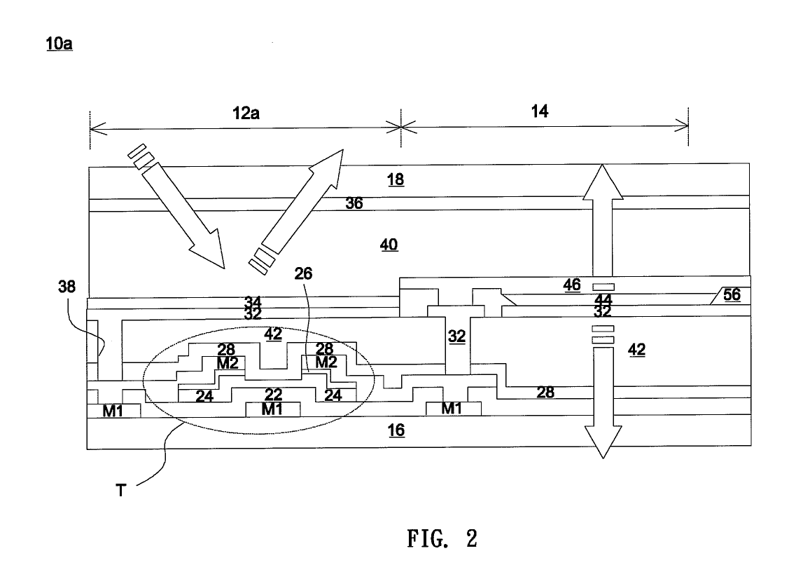

FIG. 1 shows a schematic diagram of a display structure according to an embodiment of the invention. Referring to FIG. 1, the display structure 10 includes a bistable pixel 12 and an organic light-emitting diode (OLED) pixel 14. The OLED pixel 14 is self-luminous and has wide viewing angles, high brightness and high response speed. In comparison, the bistable pixel 12 is power-saving due to bistable characteristics. FIG. 2 shows a schematic cross-section illustrating electrode structures of a display structure according to an embodiment of the invention. As shown in a display structure 10a of FIG. 2, the bistable pixel is a cholesteric liquid crystal pixel 12a, and the electrode structures of the cholesteric liquid crystal pixel 12a and the OLED pixel 14 are formed on the same side (transparent substrate 16). In this embodiment, the cholesteric liquid crystal pixel 12a includes at least one thin film transistor T. In the thin film transistor T, a first metal layer M1 is formed on the transparent substrate 16, a dielectric gate insulator 22 is formed overlying the first metal layer M1. A channel region layer 24 (pure amorphous silicon), an ohmic contact layer 26 (doped amorphous silicon) and a second metal layer M2 are formed on the gate insulator 22. A dielectric passivation insulator 28 is formed on the gate insulator 22 and the second metal layer M2, and an organic insulation layer 42 is formed on the transparent substrate 16 and covers the thin film transistor T. A transparent electrode layer 32 made from transparent conductive films are formed on the organic insulation layer 42 and electrically connected to the second metal layer M2 through a via hole 38. In one embodiment, the transparent electrode layer 32 may be electrically connected to the first metal layer Ml via the second metal layer M2 to realize a pixel compensation circuit. Besides, a black matrix layer 34 is formed on the transparent electrode layer 32. A transparent substrate 18 is disposed opposite the transparent substrate 16, and another transparent electrode layer 36 made from transparent conductive films spreads entirely on one side of the transparent substrate 18 facing the transparent substrate 16. The cholesteric liquid crystal layer 40 is interposed between the transparent substrate 16 and the transparent substrate 18. In the OLED pixel 14, an organic insulation layer 42 is formed on the passivation insulator 28, and a transparent electrode layer 32, an organic light-emitting layer 44 and a cathode layer 46 are formed on the organic insulation layer 42 in succession. The transparent electrode layer 32 serves as an anode of the OLED pixel 14. The cathode layer 46 serves as a cathode of the OLED pixel 14 and may be made from transparent conductive materials. The organic light-emitting layer 44 is formed in a region not overlapping the thin film transistor T, and a light emission area of the organic light-emitting layer 44 is defined by a bank 56. When the transparent electrode layer 32 is electrically connected to the second metal layer M2 through the via hole 38, and the cathode layer 46 serves as a common electrode (Vss) of the OLED pixel 14, a conventional OLED pixel is formed. In comparison, when the cathode layer 46 is electrically connected to the second metal layer M2 through the via hole 38, and the transparent electrode layer 32 serves as a common electrode (Vdd) of the OLED pixel 14, an inverted OLED pixel is formed. Note the transparent electrode layer 32 is merely illustrated as an example. In an alternate embodiment, the electrode layer formed on the organic insulation layer 42 may be opaque and may be a reflective electrode layer. The cholesteric liquid crystal pixel 12 is suitable for static display, and the OLED pixel 14 is suitable for animation display. For example, when the cholesteric liquid crystal pixel 12a is in a planar state, the OLED pixel 14 does not emit light. In comparison, when the cholesteric liquid crystal pixel 12a is in a focal conic state, the OLED pixel 14 emits light. Certainly, the OLED pixel is not limited to have a specific emission pattern. When the OLED pixel 14 downwardly emits light and the cholesteric liquid crystal pixel 12a displays images on a top side of the display structure 10, a dual-sided display device is provided. Further, in case the cathode layer 46 is transparent, the OLED pixel 14 may upwardly emit light. Therefore, the OLED pixel 14 may only provide top emission, only provide bottom emission, and provide both top emission and bottom emission.

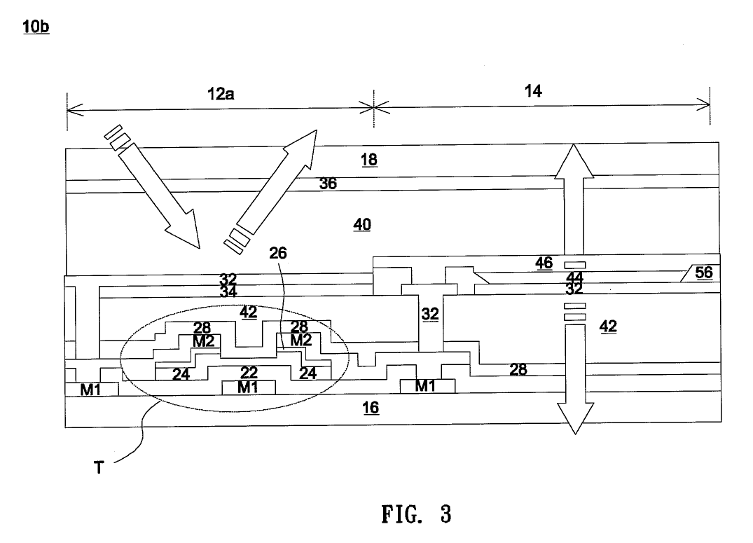

As shown in a display structure 10b of FIG. 3, in an alternate embodiment, the black matrix layer 34 is formed on the organic insulation layer 42 first, and then the transparent electrode layer 32 is formed on the black matrix layer 34 and covering the black matrix layer 34. In other words, the black matrix layer 34 may be interposed between the transparent electrode layer 32 and the organic insulation layer 42.

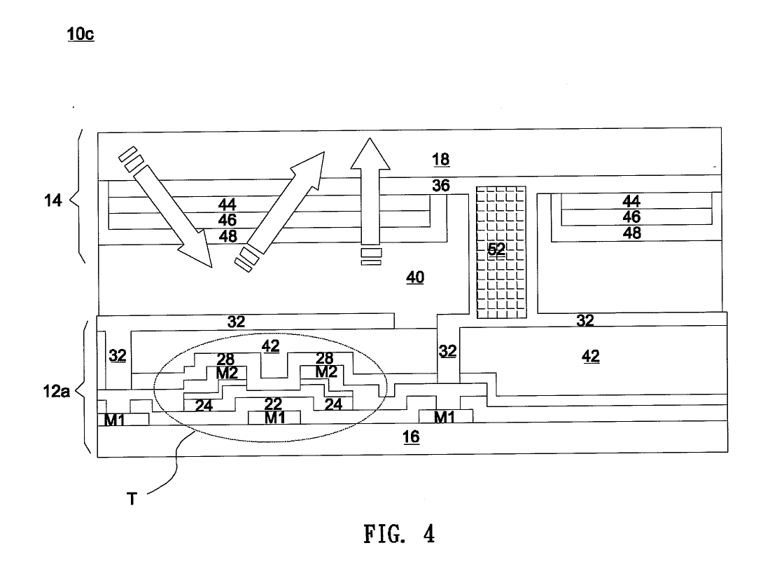

FIG. 4 shows a schematic cross-section illustrating electrode structures of a display structure according to another embodiment of the invention. As shown in a display structure 10c of FIG. 4, the bistable pixel is cholesteric liquid crystal pixel 12a, and the electrode structure of the cholesteric liquid crystal pixel 12a and the electrode structure of the OLED pixel 14 are formed on different sides. For example, the electrode structure of the cholesteric liquid crystal pixel 12a is formed on the transparent substrate 16, and the electrode structure of the OLED pixel 14 is formed on the transparent substrate 18. In this embodiment, the cholesteric liquid crystal pixel 12a includes at least one thin film transistor T and has an electrode structure similar to that shown in FIG. 2. However, compared with the display structure 10a of FIG. 2, a black matrix layer 34 is omitted from the cholesteric liquid crystal pixel 12a shown in FIG. 4 since the organic insulation layer 42 is made from an opaque material or a low-light-transmittance material. In the electrode structure of the OLED pixel 14, a transparent electrode layer 36, an organic light-emitting layer 44 and a cathode layer 46 are formed on the transparent substrate 18 in succession. The cathode layer 46 serves as a common electrode (Vcom) of the display structure 10c, and a barrier layer 48 covers the organic light-emitting layer 44 and the cathode layer 46. A bump structure 52 is disposed on the transparent substrate 16 or the transparent substrate 18 to connect the transparent electrode layer 32 on the transparent substrate 16 with the transparent electrode layer 36 on the transparent substrate 18. In this embodiment, the OLED pixel 14 and the cholesteric liquid crystal pixel 12a displays images on the same side of the display structure 10c. When the cholesteric liquid crystal pixel 12a is in a planar state, the OLED pixel 14 does not emit light. In comparison, when the cholesteric liquid crystal pixel 12a is in a focal conic state, the OLED pixel 14 upwardly emits light.

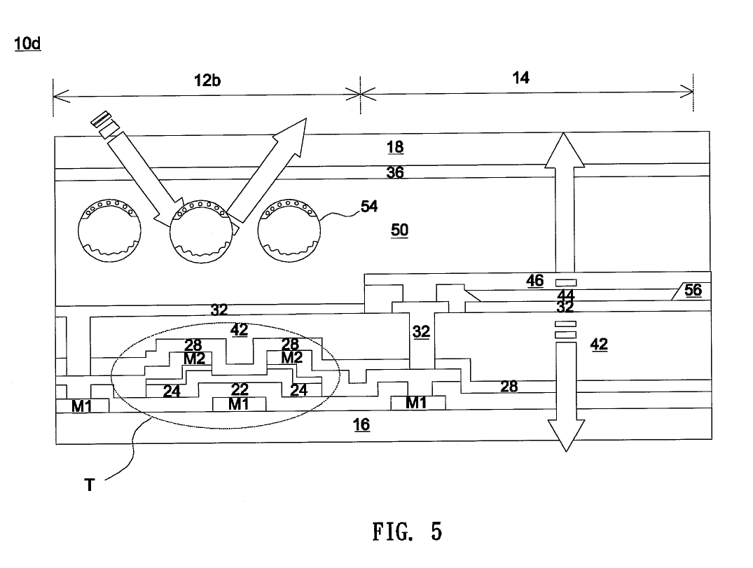

FIG. 5 shows a schematic cross-section illustrating electrode structures of a display structure according to another embodiment of the invention. As shown in a display structure 10d of FIG. 5, the bistable pixel is an electrophoretic pixel 12b, and the electrode structures of the electrophoretic pixel 12b and the OLED pixel 14 are formed on the same side (transparent substrate 16). That is, in this embodiment, the display medium layer interposed between the transparent substrate 16 and the transparent substrate 18 is an electrophoretic layer 50. The electrophoretic pixel 12b may include at least one thin film transistor T, and the electrophoretic layer 50 may include multiple micro capsules 54. When a voltage is applied across the transparent electrode layers 32 and 36, black and white particles in the micro capsules 54 migrate upwards or downwards to control light reflection and hence fulfill display effects. In this embodiment, when the OLED pixel 14 downwardly emits light and the electrophoretic pixel 12b displays images on a top side of the display structure 10, a dual-sided display device is provided. Further, in case the electrophoretic pixel 12b display images, the OLED pixel 14 may not emit light. In comparison, when the electrophoretic pixel 12b is in an off state (black state), the OLED pixel 14 may upwardly emit light.

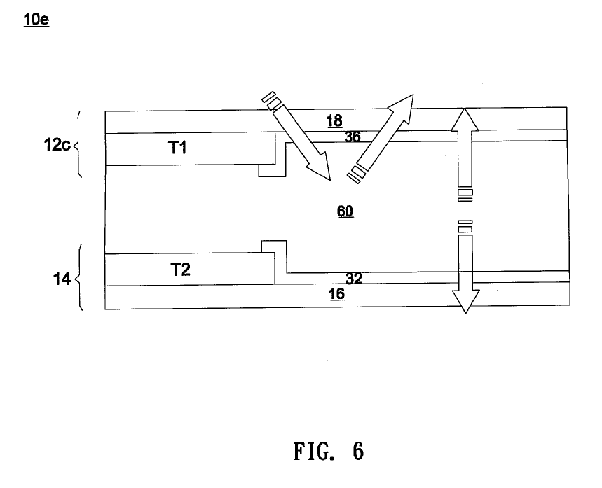

FIG. 6 shows a schematic cross-section illustrating electrode structures of a display structure according to another embodiment of the invention. As shown in a display structure 10e of FIG. 6, the display medium layer interposed between the transparent substrate 16 and the transparent substrate 18 is a polymer dispersed liquid crystal (PDLC) layer 60. The PDLC layer 60 consists of anisotropic liquid crystal droplets that are dispersed in a polymer matrix. By changing the orientation of the liquid crystal molecules with an electric field, it is possible to vary the intensity of transmitted light to form an off state and an on state and hence achieve display effects. In this embodiment, the display structure 10e has two thin film transistors T1 and T2, the thin film transistor T1 is formed on the transparent substrate 18, and the thin film transistor T2 is formed on the transparent substrate 16. Referring to FIG. 6, a polymer dispersed liquid crystal (PDLC) pixel 12c and an OLED pixel 14 are respectively formed on two sides of the display structure 10e. The PDLC pixel 12c may display images on the top side of the display structure 10e, and the OLED pixel 14 may upwardly or downwardly emit light.

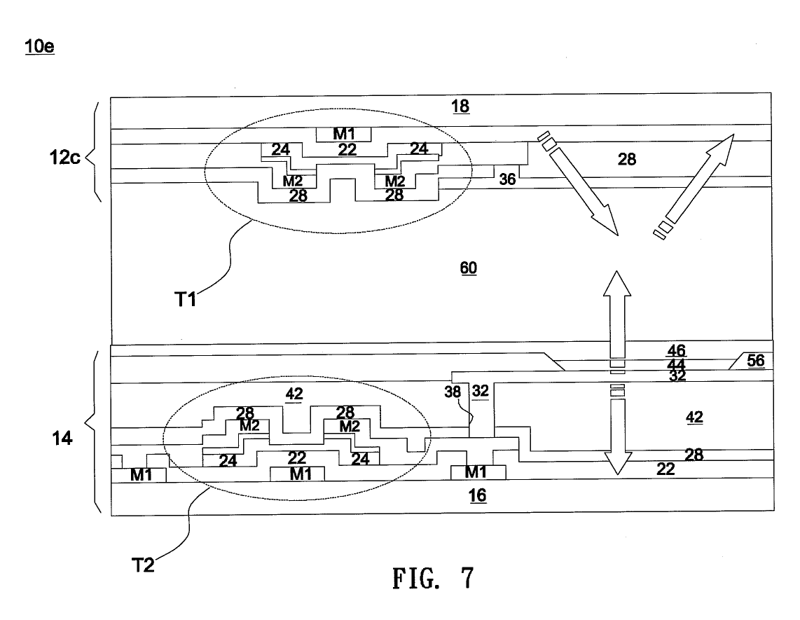

FIG. 7 shows a schematic cross-section illustrating electrode structures of a display structure shown in FIG. 6. Referring to the display structure 10e of FIG. 7, the electrode structure of the PDLC pixel 12c is formed on the transparent substrate 18, and the electrode structure the OLED pixel 14 is formed on the transparent substrate 16. In this embodiment, the PDLC pixel 12c includes at least one thin film transistor T1. In the thin film transistor T1, a first metal layer M1 is formed on the transparent substrate 18, a dielectric gate insulator 22 is formed overlying the first metal layer M1. A channel region layer 24 (pure amorphous silicon), an ohmic contact layer 26 (doped amorphous silicon), and a second metal layer M2 are formed on the gate insulator 22. A dielectric passivation insulator 28 is formed on the gate insulator 22 and the second metal layer M2. A transparent electrode layer 36 made from transparent conductive films are formed on the passivation insulator 28. In this embodiment, the OLED pixel 14 includes at least one thin film transistor T2, and the thin film transistor T2 is formed at a position overlapping the thin film transistor T1. In the thin film transistor T2, a first metal layer M1 is formed on the transparent substrate 16, a dielectric gate insulator 22 is formed overlying the first metal layer M1. A channel region layer 24 (pure amorphous silicon), an ohmic contact layer 26 (doped amorphous silicon), and a second metal layer M2 are formed on the gate insulator 22. A dielectric passivation insulator 28 is formed on the gate insulator 22 and the second metal layer M2. An organic insulation layer 42 is formed on the transparent substrate 16 and covers the thin film transistor T2. A transparent electrode layer 32 made from transparent conductive films are formed on the organic insulation layer 42 and electrically connected to the second metal layer M2 through a via hole 38. In one embodiment, the transparent electrode layer 32 may be electrically connected to the first metal layer M1 via the second metal layer M2 to realize a pixel compensation circuit. A transparent substrate 18 is disposed opposite the transparent substrate 16. The PDLC layer 60 is interposed between the transparent substrate 16 and the transparent substrate 18. In the OLED pixel 14, a transparent electrode layer 32, an organic light-emitting layer 44 and a cathode layer 46 are formed on the organic insulation layer 42 in succession. The transparent electrode layer 32 serves as an anode of the OLED pixel 14, and the cathode layer 46 serves as a cathode of the OLED pixel 14. The organic light-emitting layer 44 is formed in a region not overlapping the thin film transistor T2, and a light emission area of the organic light-emitting layer 44 is defined by a bank 56. The transparent electrode layer 32 (anode) may be electrically connected to the second metal layer M2 through the via hole 38, and the cathode layer 46 may serve as a common electrode (Vss) of the OLED pixel 14. Besides, the cathode layer 46 may also serve as a common electrode of the PDLC pixel 12c.

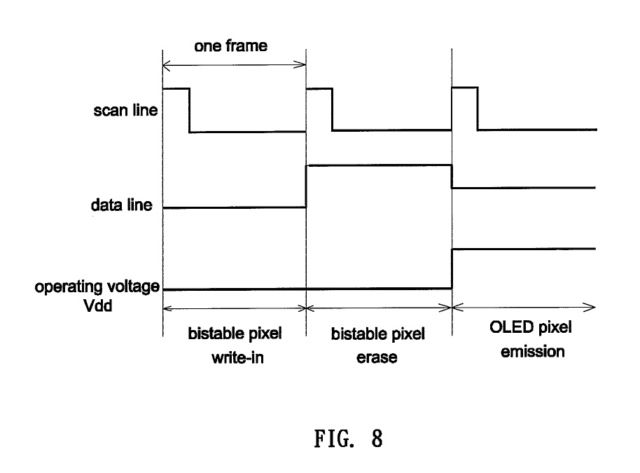

FIG. 8 shows a timing diagram illustrating a pixel drive scheme for a display structure according to an embodiment of the invention. Taking the display structure shown in FIG. 1 as an example, a pixel driving circuit for each display structure includes three kinds of signal control lines, namely data lines, scan lines, and Vdd lines, and the drive scheme may be divided into three stages:

1. Write-in of a bistable pixel: the first metal layer M1 is conducting since the scan lines are in a high-level state. Therefore, low-level signals of date lines are fed in to turn on the bistable pixel 12. Meanwhile, Vdd voltage signals are set in a low-level state to prevent the OLED pixel 14 from being mistakenly turned on.

2. Erase of a bistable pixel: the bistable pixel 12 needs to be erased before the OLED pixel 14 starts to emit light. At this stage, the voltage across a bistable cell is in a high-level state to allow for a dark state of the bistable pixel 12, and Vdd voltage signals are set in a low-level state to prevent the OLED pixel 14 from being mistakenly turned on; and

3. Emission of an OLED pixel: when the first metal layer M1 is conducting as the scan lines are in a high-level state, signals of date lines are fed in and Vdd voltage signals are set in a high-level state. Therefore, the OLED pixel 14 is allowed to display images in response to different voltage levels transmitted from data lines.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A display structure, comprising:
a first transparent substrate and a second transparent substrate opposite the first transparent substrate;
a display medium layer interposed between the first transparent substrate and the second transparent substrate;
at least one first thin film transistor formed on the first transparent substrate;
a first insulation layer formed on the first transparent substrate and covering the first thin film transistor;
a first electrode layer formed on the first insulation layer;
an organic light-emitting layer formed on the first electrode layer and in a region not overlapping the first thin film transistor;
a cathode layer formed on the organic light-emitting layer; and
a second electrode layer formed on the second transparent substrate, wherein the second electrode layer is a transparent electrode layer.

2. The display structure as claimed in claim 1, wherein the first electrode layer is a transparent electrode layer.

3. The display structure as claimed in claim 1, wherein the first electrode layer is a reflective electrode layer.

4. The display structure as claimed in claim 1, further comprising:
a black matrix layer formed on the first electrode layer or interposed between the first electrode layer and the first insulation layer.

5. The display structure as claimed in claim 1, wherein the first insulation layer comprises an opaque material or a low-light-transmittance material.

6. The display structure as claimed in claim 1, wherein the display medium layer is a cholesterol liquid crystal layer, an electrophoretic layer, or a polymer dispersed liquid crystal layer.

7. The display structure as claimed in claim 1, further comprising:
at least one second thin film transistor formed on the second transparent substrate.

8. The display structure as claimed in claim 7, wherein the second thin film transistor is formed at a position overlapping the first thin film transistor.

9. The display structure as claimed in claim 7, wherein the cathode layer serves as a common electrode of the display structure.

10. The display structure as claimed in claim 1, wherein the first thin film transistor is electrically connected to either the first electrode layer or the cathode layer.

11. The display structure as claimed in claim 10, wherein either the first electrode layer or the cathode layer serves as a common electrode of the display structure.

12. The display structure as claimed in claim 1, wherein the cathode layer is made from transparent conductive material.

13. The display structure as claimed in claim 1, wherein the second electrode layer serves as a common electrode of the display structure.

14. A display structure, comprising:
a first transparent substrate and a second transparent substrate opposite the first transparent substrate;
a display medium layer interposed between the first transparent substrate and the second transparent substrate;
at least one first thin film transistor formed on the first transparent substrate;
a first insulation layer formed on the first transparent substrate and covering the first thin film transistor;
a first electrode layer formed on the first insulation layer;
a second electrode layer formed on the second transparent substrate and electrically connected to the first electrode layer, wherein the second electrode layer is a transparent electrode layer;
an organic light-emitting layer formed on the second electrode layer; and
a cathode layer formed on the organic light-emitting layer.

15. The display structure as claimed in claim 14, further comprising:
a bump structure formed on the first transparent substrate or the second transparent substrate to connect the first electrode layer with the second electrode layer.

16. The display structure as claimed in claim 14, wherein the display medium layer is a cholesterol liquid crystal layer, an electrophoretic layer, or a polymer dispersed liquid crystal layer.

17. The display structure as claimed in claim 14, wherein the cathode layer serves as a common electrode of the display structure.

18. The display structure as claimed in claim 14, further comprising:
a barrier layer covering the organic light-emitting layer and the cathode layer.

19. A display structure having at least one organic light-emitting diode (OLED) pixel and at least one bistable pixel adjacent to or opposite from each other, wherein the OLED pixel displays images when the bistable pixel is turned off, and the bistable pixel displays images when the OLED pixel is turned off.

20. The display structure as claimed in claim 19, wherein a Vdd voltage signal is in a low-level state when a write-in operation and an erase operation are performed on the bistable pixel, and the Vdd voltage signal is in a high-level state when the OLED pixel is turned on to display images.
